(19) United States
(12) Patent Application Publication
(10) Pub. No.: US 2015/0195903 A1
(43) Pub. Date: Jul. 9, 2015

(54) LAMINATE FOIL ASSEMBLY FOR A PRINTED PRODUCT APPARATUS AND METHOD OF MANUFACTURING THE SAME

(71) Applicant: lllinois Tool Works Inc., Glenview, IL (US)

(72) Inventors: Sundareshwaran Sadasivan, Plainsboro, NJ (US); John J. Dick, Torfaen (GB); Norbert Dieter Hell, Rhodt (DE); Matthew D. Beavis, Cardiff (GB); John H. Schneider, Frankfort, IL (US)

(21) Appl. No.: 14/570,558

(22) Filed: Dec. 15, 2014

Related U.S. Application Data
(60) Provisional application No. 61/923,794, filed on Jan. 6, 2014.

(51) Int. Cl. H05K 1/02; H05K 3/00; B32B 37/24; B32B 27/06; B32B 37/00; B32B 38/10; B32B 15/08; H05K 1/09; B32B 37/12

(52) U.S. Cl. CPC H05K 1/0296; H05K 1/09; H05K 3/00; B32B 37/24; B32B 37/12; B32B 37/025; B32B 38/10; B32B 15/08; B32B 27/06; H05K 2201/0355; H05K 2201/0338; B32B 2457/08; H05K 2203/066; B32B 2250/02; B32B 2255/10

(57) ABSTRACT

A foil assembly of a printed product includes a metallic layer and a polymer layer. The metallic layer forms conductive bodies that can be detected by a touch-sensitive device. The polymer layer is coupled with the metallic layer and includes a pigment that is reflective and/or opaque and a flexible binder material. The polymer layer absorbs changes in shape of an adhesive between the foil assembly and the printed product apparatus to prevent cracking. The foil assembly may include a tie coat layer that couples the metallic layer with the adhesive and/or another tie coat layer on the other side of the metallic layer which bonds to first side of a second metallic layer. The second side of the second metallic layer includes a tie coat that couples the complete assembly with the adhesive of the printed product apparatus.

### CROSS-REFERENCE TO RELATED APPLICATIONS

This application claims priority to U.S. Provisional Application No. 61/923,794, which was filed on 6 Jan. 2014, and the entire disclosure of which is incorporated herein by reference.

### BACKGROUND

Some printed products include one or more layers of a conductive material (e.g., a foil) that is used to communicate information to a touch-sensitive computing device. For example, these types of printed products can include paper, cardboard cards, pages, films (e.g., plastic beads that are extruded onto films, such as polyethylene, polypropylene, biaxially oriented polypropylene, polyester films, etc.), or the like, that include one or more metallic foil layers beneath the printed surface of the printed product apparatus. The foil layers can be arranged in a designated pattern such that, when the printed product apparatus is placed onto a touch screen of touch-sensitive computing device (e.g., a tablet computer, mobile phone, or the like), the device is able to read information from the printed product apparatus. Various different types of information can be communicated to the device in this way, such as a website that provides a user with additional information related to the information printed on the printed product apparatus.

But, these printed products are not without drawbacks. The foil layers in these products typically are coupled with a paper or other substrate of the product by an adhesive that changes size during curing. For example, an oxidative glue may be used to bind the foil layer to the paper substrate of a printed product apparatus. During curing, the glue shrinks in size. Due to the brittleness of the foil layer, this shrinking can cause cracking or other damage to the foil layer. This damage can prevent the information that is encoded in the patterns of the foil layer from being read by the touch-sensitive computing device. As a result, a relatively large amount of the printed products are unusable.

### BRIEF DESCRIPTION

In one aspect of the inventive subject matter described herein, a cold foil assembly or transfer laminating foil assembly has been developed to provide improved and robust functionality to touch code technology. The assembly provides interactivity of a variety of products for a user with any computing device that employs a multi-touch capacitive touch screen (or other touch-sensitive input screen), such as in tablet computers and mobile phones. The touch code technology allows for covert codes (e.g., information) to be represented by one or more patterns or other arrangements of conductive bodies in the assembly. This information can be read by a touch-sensitive device when the assembly is brought into contact or relatively close proximity to the touch-sensitive screen of the device.

In one embodiment, the foil assembly is affixed to a product substrate with an adhesive (e.g., an oxidative glue or other type of laminating glue, such as a two component laminating adhesive, a single component water-based laminating adhesive, or other type of adhesive). The product substrate can be formed from a variety of materials. For example, the substrate can be paper, card stock, cardboard, or the like. Alternatively, the substrate can be formed from or can be one or more polymeric films, laminate film structures (e.g., combinations of polyester, biaxially oriented polypropylene, or the like, or nylon based films laminated to polyethylene, polypropylene, or multi-layer barrier films that include polyethylene or polypropylene), polyvinyl chloride, polycarbonate, rigid polymeric substrates (e.g., materials used for bottles, trays, lids, cups/jars, plastic cards, or any other rigid plastic structure, such as an interactive or security feature on high value plastic extruded or molded products), or the like.

The foil assembly is at least partially conductive (e.g., metallic) and can be pigmented in order to develop certain mechanical properties, as described below. These properties include flexibility that assists in preventing cracking or other damage of one or more metallic layers in the assembly when the adhesive changes size during curing. Additional properties can include, but are not limited to, stable pigment (e.g., white pigment) dispersion in the assembly due to sufficiently high polarity, balance between brittleness and flexibility of the assembly (and thus providing improved separation of the assembly from a carrier), reducing minimizing crack formation in the assembly after being transferred to the substrate, and the like. For example, the foil assembly may have optical properties, such as a light reflective property. In one embodiment, incident light on the foil assembly is reflected by both a white (or other color) pigment in a polymer layer of the foil assembly and the aluminum (or other material, such as gold, silver, chromium, or other conductive metal or alloy) in a metallic layer of the foil assembly. The reflected light rays from each point in the assembly will potentially interfere or mix in order to produce what is called as “scattered light” that makes information that is encoded in patterns or other arrangements of conductive bodies in the foil assembly at least partially invisible or imperceptible to an ordinary human being without magnifying aids.

For example, the foil assembly provides for reflectivity, which allows the electronic code invisible to a user looking at the printed product apparatus, but still decipherable (e.g., able to be detected) by a touch-sensitive computing device. For example, the foil assembly may have a reflective white background that can be printed onto with inks to convey additional information to a reader, enhance attractiveness of the printed product apparatus, and the like. Additionally, this surface onto which inks can be printed can have a relatively high dyne level to ensure good flow of the inks. The surface can have sufficient polarity to provide adhesion of the ink to the foil assembly.

While being flexible to prevent or reduce cracks in the metallic layer(s) of the foil assembly, the foil assembly also can provide some brittleness that is balanced with the flexibility. Such a balance can be useful to assist in separating the foil assembly from a carrier during manufacture of the assembly. For example, the brittleness of the assembly can help with cleanly and sharply separating the assembly from the carrier while the flexibility of the assembly maintains the integrity of the entire structure of the assembly as the adhesive in the assembly undergoes phase transformation during curing (which could otherwise create cracks in the metallic layer(s), as described above).

The flexibility of the foil assembly can be provided by one or more polymer layers. In one aspect, the polymer layer is formed from a binder material (also referred to as a resin material) and a pigment that is dispersed in the binder material. The ratio of pigment-to-binder material can be controlled to provide additional strength to the foil assembly and thereby further reduce or prevent the formation and/or propagation of cracks in the foil assembly. This polymer layer may have a relatively high glass transition temperature to provide some brittleness to the foil assembly, but also have a relatively large molecular weight to provide the flexibility of the foil assembly. The resin of the polymer layer also can have a relatively large polarity (e.g., higher carboxylation), which helps in dispersing the pigment in the polymer layer. In one aspect, the pigment that is dispersed in the resin is a reflective white pigment, such as TiO₂ or another material. The relatively large polarity also can help to prevent particles of the pigments from re-agglomerating with each other.

In one example of the inventive subject matter described herein, a foil assembly of a printed product apparatus includes a metallic layer and a polymer layer. The metallic layer forms conductive bodies configured to be detected by a touch-sensitive computing device when the printed product apparatus is placed in contact with or near the touch-sensitive computing device in order for the touch-sensitive computing device to read information from the metallic layer. The polymer layer is coupled with the metallic layer and includes a pigment dispersed within a binder material. The pigment is at least one of reflective or opaque and the binder material is at least partially flexible. The polymer layer absorbs changes in shape of an adhesive that couples the metallic layer and the polymer layer to the printed product apparatus to prevent cracking of the metallic layer.

In another example of the inventive subject matter described herein, a method includes dispersing a pigment that is at least one of reflective or opaque in a binder material that is at least partially flexible to form a polymer layer, coupling the polymer layer to a metallic layer, and adhering the metallic layer and the polymer layer to a substrate of a printed product apparatus with an adhesive that changes shape during curing of the adhesive. The adhesive may be provided in one or more patterns on the substrate. When the foil assembly is adhered to the substrate, a carrier body on which the foil assembly is disposed is pulled from the substrate such that the adhesive pulls portions of the foil assembly (including the portions of the metallic layer that correspond with or are disposed above the adhesive) from the carrier body. The remaining portion of the foil assembly that is on the substrate is in the shape of the one or more patterns. These patterns are configured to be detected by a touch-sensitive computing device when the printed product apparatus is placed in contact with or near the touch-sensitive computing device in order for the touch-sensitive computing device to read information from the metallic layer. The polymer layer absorbs changes in the shape of the adhesive to prevent cracking of the metallic layer.

In another example of the inventive subject matter described herein, a printed product apparatus includes a substrate formed from at least one of paper, card stock, cardboard, or a film, and a foil assembly coupled with the substrate by an adhesive. The foil assembly includes a metallic layer having plural conductive bodies arranged in one or more patterns and a polymer layer comprising a pigment that is at least one of reflective or opaque dispersed in a binder material. The conductive bodies are arranged in the one or more patterns such that placement of the substrate or foil assembly on or near a touch screen of a touch-sensitive computing device causes the touch-sensitive computing device to detect the one or more patterns and take one or more responsive actions. The polymer layer is at least partially flexible in order to absorb changes in shape of the adhesive and prevent cracking in the metallic layer.

In another example of the inventive subject matter described herein, a method includes dispersing a pigment that is at least one of reflective or opaque in a binder material that is at least partially flexible to form a polymer layer, and coupling the polymer layer and a tie coat layer to a such that the metallic layer is between the polymer layer and the tie coat layer. The metallic layer has conductive bodies arranged in one or more patterns. The method also includes adhering the tie coat layer to a substrate of a printed product apparatus by heating the tie coat layer so that the tie coat layer at least partially melts and adheres to the substrate. The one or more patterns of the conductive bodies in the metallic layer are configured to be detected by a touch-sensitive computing device when the printed product apparatus is placed in contact with or near the touch-sensitive computing device in order for the touch-sensitive computing device to read information from the metallic layer. The polymer layer absorbs changes in the shape of the tie coat layer to prevent cracking of the metallic layer.

In another example of the inventive subject matter described herein, a printed product apparatus includes a substrate and a foil assembly. The substrate is formed from at least one of paper, card stock, cardboard, a polymeric film, a laminate film structure, polyvinyl chloride, polycarbonate, or a rigid polymeric body. The foil assembly is coupled with the substrate, and includes a metallic layer having plural conductive bodies arranged in one or more patterns, a polymer layer comprising a pigment that is at least one of reflective or opaque dispersed in a binder material, and a tie coat layer coupled to the substrate. The conductive bodies are arranged in the one or more patterns such that placement of the substrate or foil assembly on or near a touch screen of a touch-sensitive computing device causes the touch-sensitive computing device to detect the one or more patterns and take one or more responsive actions. The polymer layer is at least partially flexible in order to absorb changes in shape of the adhesive and prevent cracking in the metallic layer.

### BRIEF DESCRIPTION OF THE DRAWINGS

The present inventive subject matter will be better understood from reading the following description of non-limiting embodiments, with reference to the attached drawings (which are not necessarily drawn to scale), wherein below:

FIG. 1 illustrates a touch-sensitive computing device detecting information encoded in a printed product apparatus that includes a foil assembly in accordance with one embodiment of the inventive subject matter described herein;

FIG. 2 is a cross-sectional view of one example of the printed product apparatus along line A-A shown in FIG. 1;

FIG. 3 is a cross-sectional view of the foil assembly shown in FIG. 2 on a carrier body according to one example of the inventive subject matter described herein;

FIG. 4 illustrates a flowchart of a method for manufacturing a printed product apparatus having a foil assembly that is readable by a touch-sensitive computing device;

FIG. 5 is first magnified image of a conductive body in a foil assembly that does not include the composite polymer layer shown in FIG. 2 of the foil assembly also shown in FIG. 2 and that has a reduced thickness of a metallic layer;

FIG. 6 is a second magnified image of the conductive body shown in FIG. 5;

FIG. 7 is first magnified image of a conductive body in a foil assembly that does not include the composite polymer layer shown in FIG. 2 of the foil assembly shown in FIG. 2;

FIG. 8 is a second magnified image of the conductive body shown in FIG. 7;

FIG. 9 is first magnified image of a conductive body in a foil assembly that includes a composite polymer layer and increased thickness of a metallic layer relative to the conductive body shown in FIGS. 5 and 6;

FIG. 10 is a second magnified image of the conductive body shown in FIG. 9;

FIG. 11 is first magnified image of the conductive body shown in FIG. 1 in the foil assembly 202 shown in FIG. 2 that includes the composite polymer layer shown in FIG. 2;

FIG. 12 is a second magnified image of the conductive body shown in FIG. 11;

FIG. 13 is a third magnified image of the conductive body shown in FIG. 11;

FIG. 14 is a cross-sectional view of another example of a printed product apparatus;

FIG. 15 is a cross-sectional view of the multi-layered foil assembly shown in FIG. 14 on a carrier body according to one example of the inventive subject matter described herein; and

FIG. 16 illustrates a flowchart of a method for manufacturing a printed product apparatus having a foil assembly that is readable by a touch-sensitive computing device.

### DETAILED DESCRIPTION

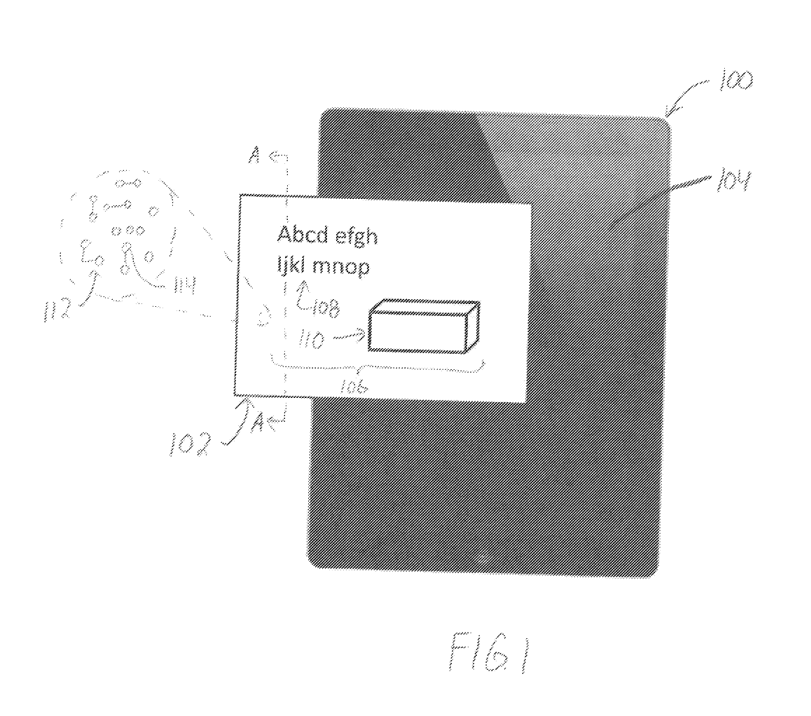

FIG. 1 illustrates a touch-sensitive computing device 100 detecting information encoded in a printed product apparatus 102 that includes a foil assembly in accordance with one embodiment of the inventive subject matter described herein. The device 100 includes a touch-sensitive input screen 104. The device 100 can detect one or more touches of the screen 104, such as when a user touches the screen 104 with one or more fingers. The printed product apparatus 102 includes indicia 106 printed on the product 102, such as text 108, images 110, or the like. The indicia 106 are visible to an ordinary human being without the aid of magnifying devices.

The foil assembly of the printed product apparatus 102 includes one or more metallic patterns 112 formed from metallic bodies 114. When the printed product apparatus 102 is placed into contact or relatively close proximity with the input screen 104 of the device 100, the device 100 can sense the presence of the bodies 114 and can determine the patterns 112 in which the bodies 114 are formed. The device 100 may be programmed to associate different patterns 112 with different types of information. For example, some patterns 112 of the bodies 114 may represent links to websites or other information. The device 100 can determine the information represented by the patterns 112 and take one or more responsive actions, such as by automatically displaying information related to the indicia 106 printed on the product 102, automatically displaying a web page associated with the indicia 106, or another action.

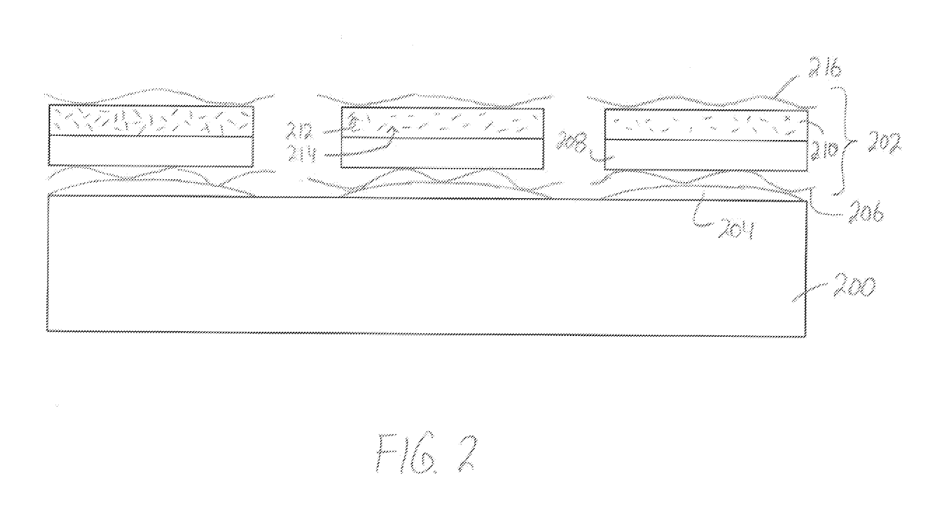

FIG. 2 is a cross-sectional view of one example of the printed product apparatus 102 along line A-A shown in FIG. 1. The printed product apparatus 102 includes a substrate 200, which can be formed from paper, card stock, cardboard, film, or another material. The substrate 200 is coupled with a foil assembly 202 by an adhesive 204. In the illustrated example, the adhesive 204 is applied in discrete locations, such as by forming spaced-apart islands of the adhesive 204. Optionally, a continuous sheet of adhesive 204 can extend between the substrate 200 and the foil assembly 202. While only three islands of the adhesive 204 are shown, optionally, a fewer or larger number of islands of the adhesive 204 may be used.

The foil assembly 202 includes a flexible tie coat layer 206 that is coupled with the adhesive 204. The tie coat layer 206 may be flexible in that the tie coat layer 206 is more prone or likely to bend than to break or crack when bent. Similar to the adhesive 204, the tie coat layer 206 is shown as being formed from several separate and spaced-apart bodies. Optionally, the tie coat layer 206 may continuously extend over a larger area or portion of the substrate 200 than what is shown in FIG. 2. The thickness of the tie coat layer 206 may be at least 0.05 microns and no greater than 0.1 microns. Optionally, the thickness of the tie coat layer 206 may be another value.

The tie coat layer 206 is connected with a metallic layer 208. The metallic layer 208 is formed from one or more metals or metal alloys, such as aluminum or another metal (e.g., gold, silver, etc.). The metallic layer 208 is formed into the separate conductive bodies 114 described above in connection with FIG. 1. The scale of FIG. 2 is different from that of FIG. 1 so that the bodies 114 in the metallic layer 208 are more visible. In one embodiment, the metallic layer 208 is a brittle layer that is more prone to cracking or otherwise breaking than to bending or otherwise deforming when the metallic layer 208 is bent. The thickness of the metallic layer 208 may be relatively thick, such as a thickness that provides an optical density of the metallic layer 208 that is 2 to 2.5. Alternatively, the thickness of the metallic layer 208 may be such that the optical density is another value, such as 2.25 to 2.75, 1.5 to 2, 2.5 to 3, or another value.

The metallic layer 208 is coupled with a composite polymer layer 210. The polymer layer 210 also is formed from several separate and spaced-apart bodies that are joined with the bodies of the metallic layer 208. Alternatively, the polymer layer 210 may continuously extend across multiple bodies of the metallic layer 208. The polymer layer 210 is formed from a pigment 212 that is dispersed within a resin body 214. The resin body 214 optionally may be referred to as resin material, binder material, and/or a binder body. The resin body 214 provides the bulk of the polymer layer 210, with the pigment 212 mixed therein. The pigment 212 can be reflective in order to hide the conductive bodies 114 and/or patterns 112 formed from the conductive bodies 114 to a viewer of the printed product apparatus. For example, because the polymer layer 210 with the pigment 212 is between the viewer and the metallic layer 208, the pigment 212 can help to reflect light so that the metallic layer 208 is more difficult for the viewer to see. The pigment 212 optionally may provide color and/or opaqueness to the foil assembly 202, such as by making the foil assembly 202 white (or another color) to more closely match the appearance of the substrate 200. For example, if the printed product apparatus 102 (shown in FIG. 1) is to be a business card or sheet of paper, then the pigment 212 may cause the foil assembly 202 to appear white.

The patterns 112 and bodies 114 may not be visible due to opacity of pigments in the composite polymer layer. The pigments cause light scattering, which prevents the patterns 112 and bodies 114 from being seen by a human being without aid of a magnification. If the composite polymer layer is printed on with additional inks (e.g., over printed), this over printing can also prevent the patterns 112 and bodies 114 from being visible.

In one aspect, the pigment 212 includes or is formed from titanium dioxide (TiO₂). This pigment 212 can have a relatively large refractive index to assist in reflecting light. For example, the refractive index of the pigment 212 may be larger than 2.0, such as a refractive index of 2.67 or another value. The large refractive index helps to provide light scattering properties which can make the patterns 112 (shown in FIG. 1) of the conductive bodies 114 of the metallic layer 208 not visible to an ordinary human being without the aid of a magnifying device. The pigment 212 may act as a conductive body or as a semiconductor. This property of the pigment 212 can assist in providing information to the touch sensitive computing device 100.

The resin body 214 of the polymer layer 210 can exhibit both brittle and flexible characteristics. For example, the resin body 214 may be selected such that the glass transition temperature of the resin body 214 is at least 125 degrees Celsius and that is less than 165 degrees Celsius. Optionally, the resin body 214 may be selected to have another glass transition temperature, such as 125 to 135 degrees Celsius, or another temperature).

The flexible nature of the resin body 214 may be due to the relatively large molecular weight of the resin body 214 (e.g., 100,000 Daltons, or another value). In one aspect, the resin body 214 is an isoborneol-methyl methacrylate copolymer. Optionally, another material may be used. The resin body 214 may have a relatively large degree of carboxylation, such that the resin body 214 has an acid value of 25 to 35 (or another value, such as 20 to 40, less than 25, or greater than 35) and the resin body 214 is polar. These characteristics of the resin body 214 can cause the resin body 214 to be a good dispersing agent for the pigment 212 and prevent agglomeration of the pigments 212. This large acid value also can help the polymer layer 210 adhere to the metallic layer 208 better than if the resin body 214 had a lower acid value.

The polymer layer 210 may be provided in a variety of thicknesses. In one aspect, the thickness of the polymer layer 210 is in the range of 1.5 microns to 5 microns. Optionally, this thickness may be in the range of 1.9 microns to 2.5 microns. Alternatively, another thickness or range of thicknesses may be used.

A top coat layer 216 can be coupled with the polymer layer 210. In the illustrated example, the polymer layer 210 is between the metallic layer 208 and the top coat layer 216. In another embodiment, the tie coat layer 206 and the top coat layer 216 may be the same layer. Alternatively, the tie coat layer 206 and the top coat layer 216 may be formed from the same material or materials at different times to form a single layer.

The top coat layer 216 is the portion of the foil assembly 202 that is visible to a user of the printed product apparatus 102. The top coat layer 216 can be a flexible layer in that the top coat layer 216 is more likely to bend without breaking when bent, as opposed to a brittle layer that is more likely to break when bent. For example, the top coat layer 216 may have a percent elongation at break in a range of 100% to 500%. Alternatively, the top coat layer 216 may have a percent elongation at break in a range of 150% to 350%. Alternatively, the top coat layer 216 may have another percent elongation at break. In one embodiment, the top coat layer 216 is a polyurethane or acrylic urethane class material that is synthesized using one or a combination of polyester polyol, polyether polyol, polycarbonate polyol, acrylic polyol, or the like. Optionally, another material may be used.

The top coat layer 216 can be provided in a thickness that is at least 0.1 micron and is no greater than 0.5 microns. Optionally, the thickness of the polymer layer 210 is at least 0.1 micron and is no greater than 0.2 microns. Alternatively, another the thickness of the polymer layer 210 may be thinner or thicker than the thicknesses in these ranges.

The top coat layer 216 can have a relatively large dyne level. For example, the dyne level of the top coat layer 216 may be sufficiently large to allow for inks to be easily printed onto the top coat layer 216. In one aspect, a minimum surface tension dyne level of the top coat layer 216 is at least 42 dynes. In another aspect, the minimum surface tension dyne level of the top coat layer 216 is at least 50 dynes, or another level. The indicia 106 (shown in FIG. 1) can be printed onto the top coat layer 216 using one or more inks.

As described herein, the adhesive 204 may be a material that changes shape during curing. For example, the adhesive 204 may include an oxidative glue that cures over an extended time period (e.g., several hours). During this curing, the adhesive 204 may undergo a phase transformation and shrink. This shrinkage can potentially break up the metallic layer 208 even further and form cracks in the patterns 112 and/or bodies 114 created by the metallic layer 208.

In order to prevent the curing of the adhesive 204 from cracking the relatively brittle metallic layer 208, the foil assembly 202 includes two more flexible layers on opposite sides of the metallic layer 208. For example, both the tie coat layer 206 and the top coat layer 216 may be more flexible than the metallic layer 208 so that the shrinkage of the adhesive 204 is absorbed by the flexible layers 206, 216 and does not bend the metallic layer 208 sufficiently far to form cracks or other damage in the metallic layer 208.

The foil assembly 202 can be adhered to the substrate 200 by forming the foil assembly 202 on a carrier body, delaminating the foil assembly 202 from the carrier body, and then transferring the foil assembly 202 onto the substrate 200.

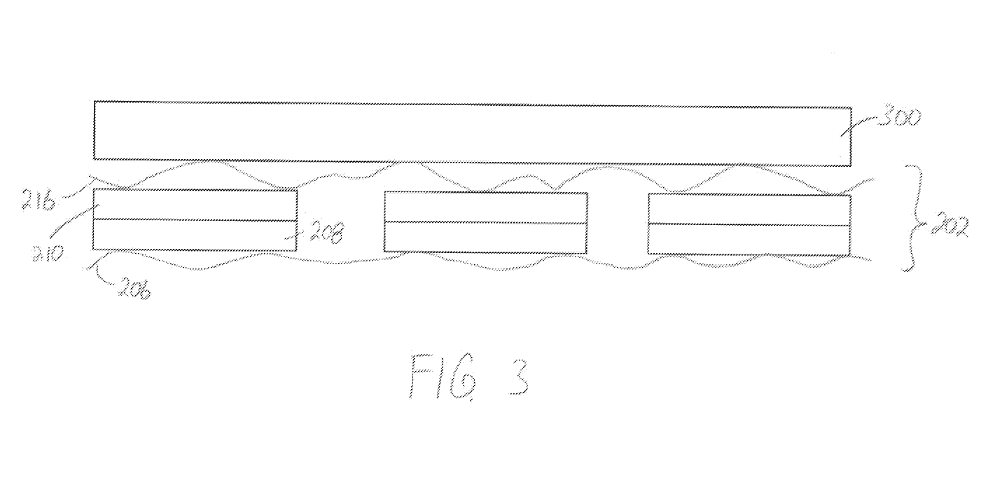

FIG. 3 is a cross-sectional view of the foil assembly 202 on a carrier body 300 according to one example of the inventive subject matter described herein. The carrier body 300 is formed from a material that temporarily bonds with the top coat layer 216 of the foil assembly 202. For example, a 12 to 24 micron thick layer of polyethylene terephthalate (PET) may form the carrier body 300. Alternatively, a different thickness and/or material may be used. The top coat layer 216 may be coupled with the carrier body 300, and the polymer layer 210 deposited thereon, such as by printing the polymer layer 210 onto the top coat layer 216 and then depositing the metallic layer 208 onto the polymer layer 210. Alternatively, another deposition technique may be used.

The metallic layer 208 is then deposited onto the polymer layer 210. In one embodiment, aluminum is vacuum metallized onto the polymer layer 210. Optionally, another material and/or deposition technique may be used to deposit the metallic layer 208. For example, for metals like gold, silver, chromium, and the like, the metallic layer 208 may be formed by sputtering the gold, silver, chromium, or other material, onto the polymer layer 210. The tie coat layer 206 is then applied to the metallic layer 208 to complete formation of the foil assembly 202.

The foil assembly 202 may then be coupled with the substrate 200 (shown in FIG. 2) by depositing the adhesive 204 (shown in FIG. 2) onto the substrate 200 and coupling the tie coat layer 206 to the adhesive 204. The adhesive 204 can be printed onto the substrate 200 in the patterns 112 (shown in FIG. 1) such that, once the foil assembly 202 is bonded to the substrate 200 by the adhesive 204, the carrier body 300 can be separated from the substrate 200 and the portions of the foil assembly 202 that are in contact with the adhesive 204 remain on the substrate 200. The tie coat layer 206 may be more strongly bonded to the adhesive 204 than the top coat layer 216 is to the carrier body 300. As a result, the carrier body 300 can be removed from the foil assembly 202, with the foil assembly 202 remaining coupled with the substrate 200 by the adhesive 204.

FIG. 4 illustrates a flowchart of a method 400 for manufacturing a printed product apparatus having a foil assembly that is readable by a touch-sensitive computing device. The method 400 may be used to create the foil assembly 202 (shown in FIG. 2) and printed product apparatus 102 (shown in FIG. 1) described above.

At 402, a refractive pigment is dispersed within a resin material to form a composite material. For example, bodies of titanium oxide can be ground up and mixed in with isoborneol-methyl methacrylate copolymer to form the material that is to be used to form the polymer layer 210 (shown in FIG. 2).

At 404, a top coat layer is coupled with a carrier body. For example, the top coat layer 216 (shown in FIG. 2) may be temporarily connected with the carrier body 300 (shown in FIG. 3). In one aspect, the top coat layer may be applied by printing the top coat layer onto the carrier body, such as using the gravure printing technique, a slot dye technique, or another technique.

At 406, the composite material formed at 402 may be deposited onto the top coat layer. In one example, the composite material may be printed onto the top coat layer to form separate, spaced-apart bodies or islands of the polymer layer 210. In one aspect, the polymer layer and the top coat layer may be printed onto the carrier body at the same time. For example, the top coat layer and the polymer layer may be applied to the carrier body in tandem. Alternatively, the polymer layer may be separately formed on the top coat layer after the top coat layer is applied to the carrier body. The polymer layer may have a lower surface tension dyne level than the top coat layer after the polymer layer dries or cures. For example, the polymer layer 210 may have a surface tension dyne level that is at least five dynes lower than the top coat layer 216.

At 408, one or more conductive materials are deposited into the polymer layer to form a metallic layer. The conductive materials may be deposited using vacuum deposition or another technique.

At 410, a tie coat layer is applied to the metallic layer. For example, the tie coat layer 206 (shown in FIG. 2) may be applied onto and coupled with the metallic layer 208 (shown in FIG. 2) to form the foil assembly 202. At 412, adhesive is applied to a substrate of a printed product apparatus. For example, the adhesive 204 (shown in FIG. 2) may be printed onto the substrate 200 (shown in FIG. 2) at or near locations where the bodies 114 and patterns 112 formed by the polymer layer 210 and metallic layer 208 are to be located.

At 414, the tie coat layer of the foil assembly is applied to (e.g., connected with) the adhesive. The adhesive may then cure to bind the foil assembly to the substrate of the printed product apparatus. As described above, the adhesive may change shape (e.g., shrink) during this curing process. The flexible top coat layer and tie coat layer, as well as the flexibility of the polymer layer, can more easily flex and move due to the changing shape of the adhesive so that the metallic layer is not bent or otherwise experience forces exerted on the metallic layer by the changing shape of the adhesive.

At 416, the carrier body can be removed from the foil assembly. During or after curing of the adhesive is complete, the carrier body can be separated from the top coat layer to leave portions of the foil assembly on the substrate. The portions of the foil assembly that remain on the substrate may be those portions that contact the adhesive on the substrate.

At 418, indicia optionally may be printed onto the top coat layer of the foil assembly, as described above. The printed product apparatus may then be placed onto a touch-sensitive input screen 104 (shown in FIG. 1) of a touch-sensitive computing device 100. The touch-sensitive computing device 100 may detect the conductive bodies 114 and/or patterns 112 of the bodies 114 based on changes in capacitance in one or more locations near the touch-sensitive input screen 104. Based on these changes in capacitance, the touch-sensitive computing device 100 may detect information represented by the bodies 114 and/or patterns 112, and use this information to take one or more responsive actions, such as display a website to a user, verify or authenticate a user (based on that user's possession of the printed product apparatus), present other information to the user (other than the information presented on the printed product apparatus), or the like.

The method 400 describes a cold foil transfer of the foil assembly onto a substrate to form a printed product. The foil assembly formed from the polymer layer, the metallic layer, the tie coat layer, and the top layer may be transferred to the substrate with the adhesive disposed thereon without application of heat. Alternatively, the foil assembly may be modified and applied using a hot stamp foil transfer. For example, with respect to the foil assembly 202, the tie coat layer 206 may be a greater thickness and no adhesive 204 may be applied to the substrate 200. Instead, such a modified foil assembly may be engaged to the substrate 200 so that the thicker tie coat layer 206 (also referred to as a size coat) contacts the substrate 200 without the adhesive 204 disposed there between. Heat and/or pressure can then be applied to cause the tie coat layer 206 to at least partially melt and bond to the substrate 200. The tie coat layer 206 may then adhere the modified foil assembly to the substrate to form the printed product. The tie coat layer 206 may change shape during this melting and bonding. The flexibility of the tie coat layer 206 and/or the flexibility of the polymer layer 210 can help to prevent cracking of the metallic layer, as described above.

As described above, one aspect of the inventive subject matter described herein provides for reduced or eliminated cracking of conductive bodies in a foil assembly of a printed product apparatus by positioning one or more flexible layers in the foil assembly. These flexible layers (e.g., the top coat layer, the tie coat layer, and/or the composite polymer layer) can absorb changes in dimension in the adhesive that binds the foil assembly to the substrate of the printed product apparatus. The presence or degree of cracking in the foil assembly may be measured by calculating a successful read rate. This read rate represents the percentage, fraction, or other measurement of how many printed product apparatuses can be read by a touch-sensitive computing device. For example, a read rate of 20% indicates that one out of five printed product apparatuses have conductive bodies 114 and/or patterns 112 in foil assemblies 202 of the printed product apparatuses that can be detected by the touch-sensitive computing device such that the touch-sensitive computing device identifies the information represented by the bodies 114 and/or patterns 112.

Without the flexible layers in the foil assembly, a successful read rate for the printed product apparatus may be relatively low, such as less than 50%, less than 10%, or another percentage or fraction. As a result, at least half of the printed product apparatuses may be unusable and are typically discarded. With the flexible layers in the foil assembly, the successful read rate can be increased, such as to a read rate that is no less than 50% (e.g., is at least 50%) or another percentage or fraction, as described below.

Additionally, inventors of the inventive subject matter described herein have discovered that changing various dimensions, amounts, or the like, of the components in the foil assembly 202 can further cause the successful read rate to increase. The increases in the read rate unexpectedly increase when certain materials, thicknesses, amounts, or the like, of the components in the foil assembly 202 are used. For example, when certain materials are used for the composite polymer layer 210, when the thickness of aluminum in the metallic layer of the foil assembly 202 is at least a designated amount, a pigment-to-binder ratio of the composite polymer layer in the foil assembly 202 is within a designated range, or the like, the read rate of the printed product apparatuses that include such a foil assembly 202 unexpectedly increases relative to using other thicknesses, ratios, or the like. The unexpected increases in the successful read rate represent further inventive aspects of the subject matter described herein. Not all embodiments of the inventive subject matter that is described and/or claimed herein, however, require these materials, dimensions, ratios, and the like. Other materials, dimensions, ratios, and the like, may be used while increasing the successful read rate of the printed product apparatuses.

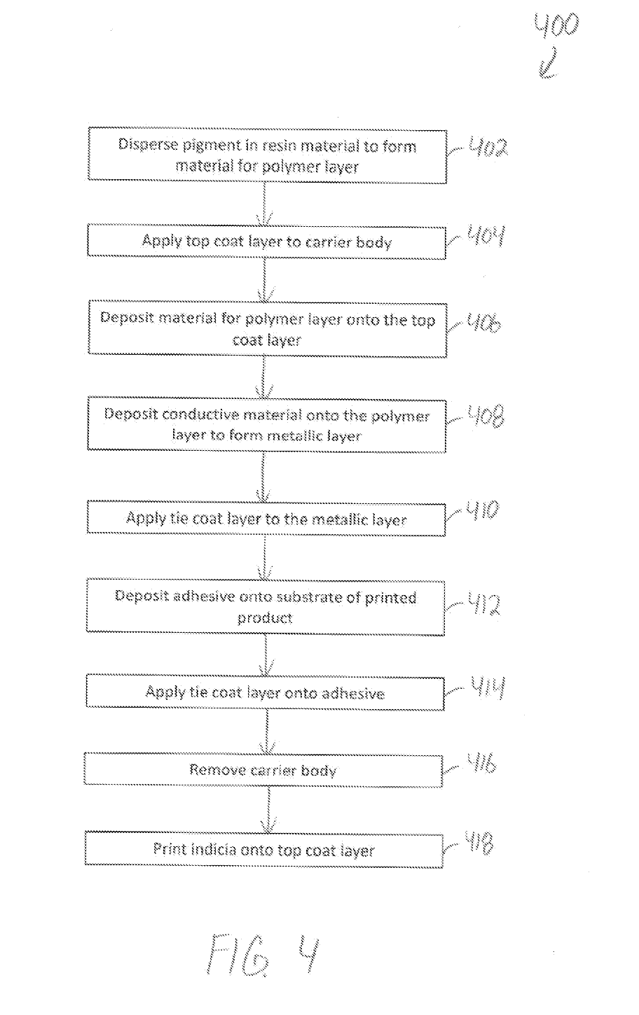

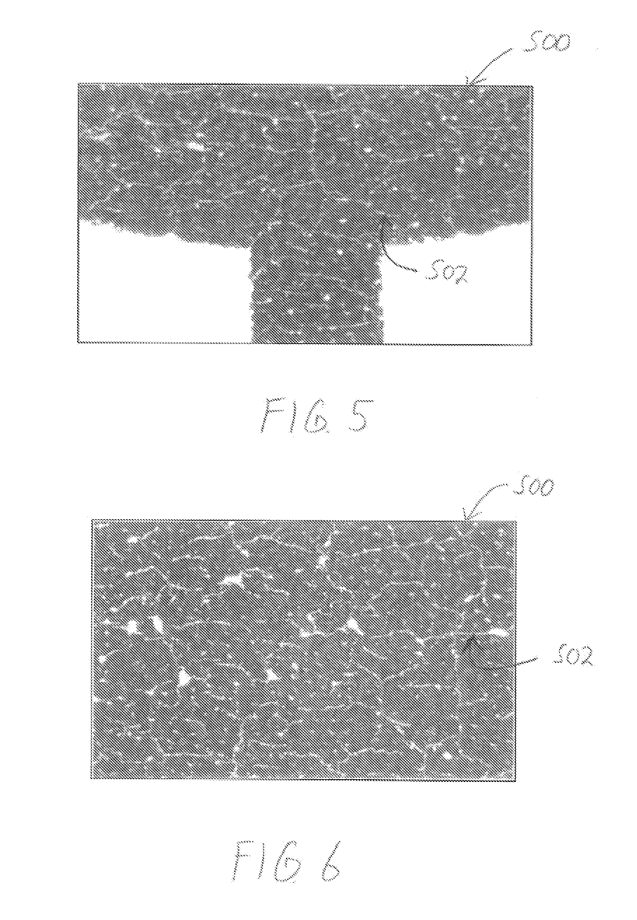

FIG. 5 is first magnified image of a conductive body 500 in a foil assembly that does not include the composite polymer layer 210 (shown in FIG. 2) of the foil assembly 202 (shown in FIG. 2) and has a reduced thickness of a metallic layer. FIG. 6 is a second magnified image of the conductive body 500 shown in FIG. 5. The conductive body 500 may be included in a foil assembly of a printed product apparatus in order to be detected by a touch-sensitive computing device, similar to as described above in connection with the conductive bodies 114 (shown in FIG. 1) described above. The images shown in FIGS. 5 and 6 are at a two hundred magnification level.

The foil assembly having the conductive body 500 in FIGS. 5 and 6 may be formed from aluminum that is deposited in a thickness that is sufficiently small to cause the optical density of the metallic layer that includes the conductive body 500 to be less than 2.0. Additionally, this foil assembly does not include the composite polymer layer 210 described above. Instead, the foil assembly that includes the conductive body 500 may have a polymer layer formed from a material such as nitrocellulose, blocked isocyanate, diaryl phthalates, or the like, that is more brittle than a material such as isoborneol-methyl methacrylate copolymer (or another material), and/or does not include the pigment 212 (shown in FIG. 2) described above. This foil assembly also may not include one or more of the top coat layer 216 (shown in FIG. 2) and/or the tie coat layer 206 (shown in FIG. 2).

As shown in FIGS. 5 and 6, the conductive body 500 includes several cracks 502 or other damage that propagate throughout relatively large portions of the conductive body 500. These cracks 502 can prevent the conductive body 500 (and/or patterns formed from plural conductive bodies 500) in the foil assembly of a printed product apparatus from being detected (e.g., read) by a touch-sensitive computing device. For example, the cracks 502 may interrupt or destroy conductive pathways used to form capacitive elements used by the touch-sensitive computing device to read the printed product apparatus. These cracks 502 are formed by shrinkage of the adhesive (e.g., oxidative glue) that couples the foil assembly having the conductive body 500 to the substrate of the printed product apparatus, as described above. The printed product apparatuses having the foil assemblies with the conductive body 500 shown in FIGS. 5 and 6 were measured to have successful read rates of less than 10%. As a result, at least 90% of the printed product apparatuses having such foil assemblies are unreadable by a touch-sensitive computing device.

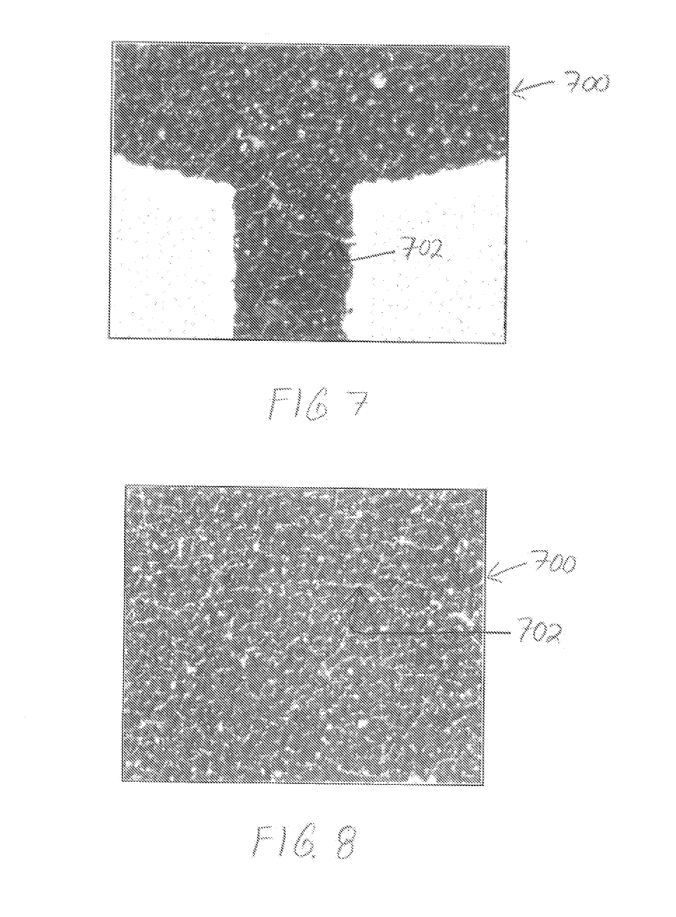

FIG. 7 is first magnified image of a conductive body 700 in a foil assembly that does not include the composite polymer layer 210 (shown in FIG. 2) of the foil assembly 202 (shown in FIG. 2). FIG. 8 is a second magnified image of the conductive body 700 shown in FIG. 7. The conductive body 700 may be included in a foil assembly of a printed product apparatus in order to be detected by a touch-sensitive computing device, similar to as described above in connection with the conductive bodies 114 (shown in FIG. 1) described above. The images shown in FIGS. 7 and 8 are at a two hundred magnification level.

The foil assembly having the conductive body 700 in FIGS. 7 and 8 may be formed from aluminum that is deposited in a thickness that is sufficiently large to cause the optical density of the metallic layer that includes the conductive body 700 to be greater than 2.0. Additionally, this foil assembly does not include the composite polymer layer 210 described above. Instead, the foil assembly that includes the conductive body 500 may have a polymer layer formed from a material such as nitrocellulose, blocked isocyanate, diary′ phthalates, or the like, that is more brittle than a material such as isoborneol-methyl methacrylate copolymer (or another material), and/or does not include the pigment 212 (shown in FIG. 2) described above. This foil assembly also may not include one or more of the top coat layer 216 (shown in FIG. 2) and/or the tie coat layer 206 (shown in FIG. 2).

As shown in FIGS. 7 and 8, the conductive body 700 includes several cracks 702 or other damage. These cracks 702 are smaller than the cracks 502 (shown in FIG. 5) of the conductive body 500 (shown in FIG. 5) shown in FIGS. 5 and 6, but still propagate through relatively large portions of the conductive body 700. Increasing the thickness of the metallic layer in the foil assembly that includes the conductive body 700 reduces the sizes of the cracks 702 relative to the thickness of the metallic layer in the foil assembly that includes the conductive body 500 shown in FIGS. 5 and 6. The printed product apparatuses having the foil assemblies with the conductive body 700 shown in FIGS. 7 and 8 were measured to have successful read rates of less than 50%. As a result, at least half of the printed product apparatuses having such foil assemblies are unreadable by a touch-sensitive computing device.

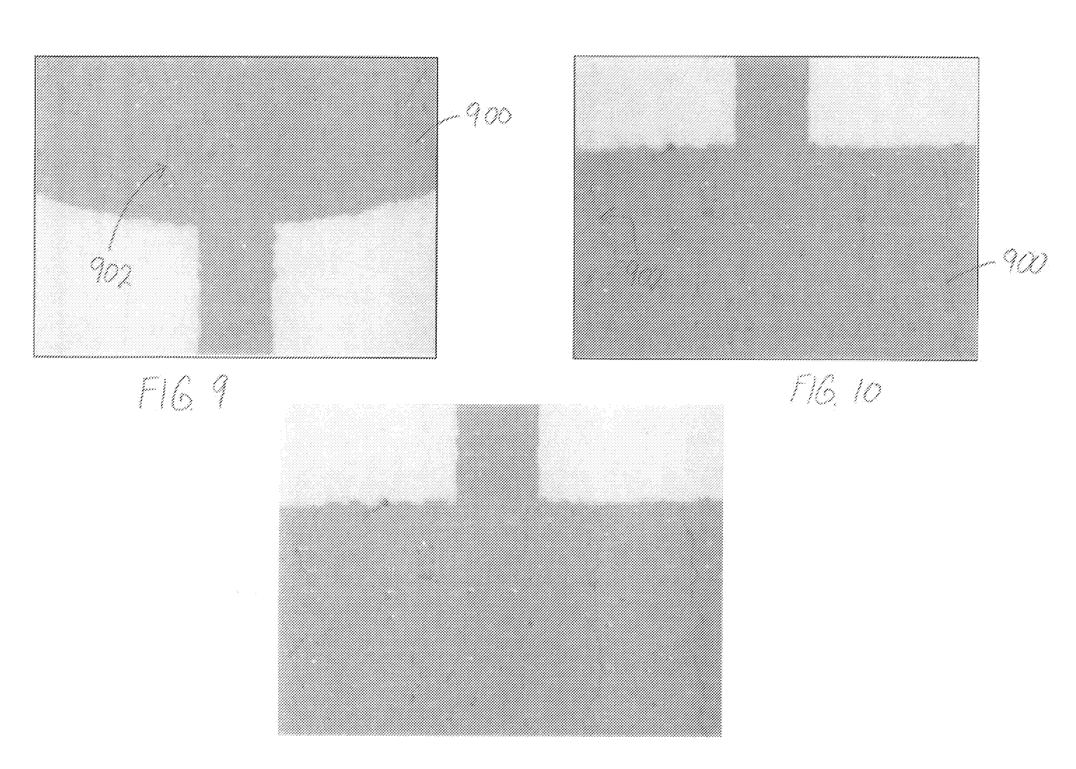

FIG. 9 is first magnified image of a conductive body 900 in a foil assembly that includes a composite polymer layer and increased thickness of a metallic layer relative to the conductive body 500 shown in FIGS. 5 and 6. FIG. 10 is a second magnified image of the conductive body 900 shown in FIG. 9. The conductive body 900 may be included in a foil assembly of a printed product apparatus in order to be detected by a touch-sensitive computing device, similar to as described above in connection with the conductive bodies 114 (shown in FIG. 1) described above. The images shown in FIGS. 9 and 10 are at a two hundred magnification level.

The foil assembly having the conductive body 900 in FIGS. 9 and 10 may be formed from aluminum that is deposited in a thickness that is sufficiently large to cause the optical density of the metallic layer that includes the conductive body 700 to be greater than 2.0. Additionally, this foil assembly includes a polymer layer having a white pigment dispersed in the polymer layer, but in a binder material or resin that is more brittle than the binder material or resin of the polymer layer 210. For example, the binder material or resin in the foil assembly having the conductive body 900 in FIGS. 9 and 10 may be more brittle than isoborneol-methyl methacrylate copolymer, may have a molecular weight that is less than 100,000 Daltons, or the like.

The composite polymer layer of the foil assembly having the conductive body 900 shown in FIGS. 9 and 10 may have a ratio of the amount of pigments 212 (shown in FIG. 2) to the amount of resin body 214 (shown in FIG. 2) in the composite polymer layer of the foil assembly having the conductive body 900 that is less than 0.5 or that is greater than one. For example, there may be more than twice as much resin body 214 than the amount of pigments 212 (e.g., a ratio that is less than 0.5), or there may be a larger amount of pigments 212 than resin body 214 (e.g., a ratio that is greater than one (e.g., the ratio is outside of a range of 0.5 to one). Optionally, another ratio may be used. This foil assembly also may include one or more of the top coat layer 216 (shown in FIG. 2) and/or the tie coat layer 206 (shown in FIG. 2).

As shown in FIGS. 9 and 10, the conductive body 900 includes fewer cracks 902 or other damage than the conductive bodies 500, 700 shown in FIGS. 5 through 8. Increasing the thickness of the metallic layer in the foil assembly that includes the conductive body 900 and/or using the pigments 212 in the resin body 214 of a composite polymer layer reduces the sizes and/or number of the cracks 902 relative to the conductive bodies 500, 700 described above. The printed product apparatuses having the foil assemblies with the conductive body 900 shown in FIGS. 9 and 10 were measured to have successful read rates of at least 50% but less than 70%. As a result, at least half of the printed product apparatuses having such foil assemblies are readable by a touch-sensitive computing device, but up to 30% of these printed product apparatuses may still be unreadable.

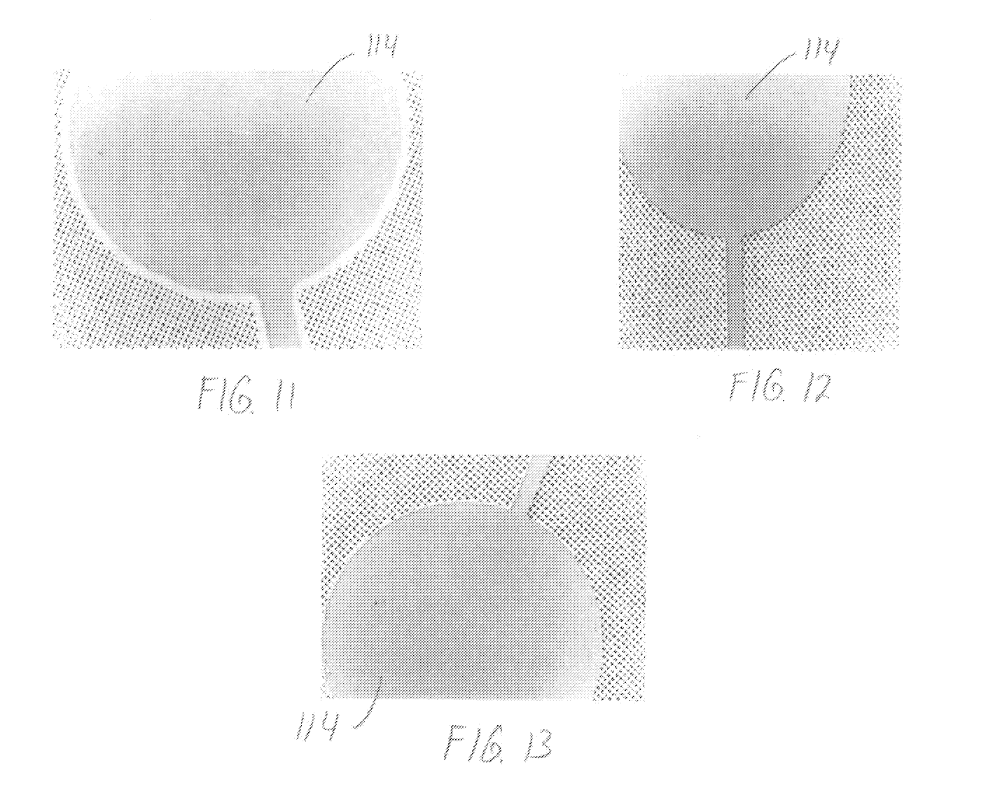

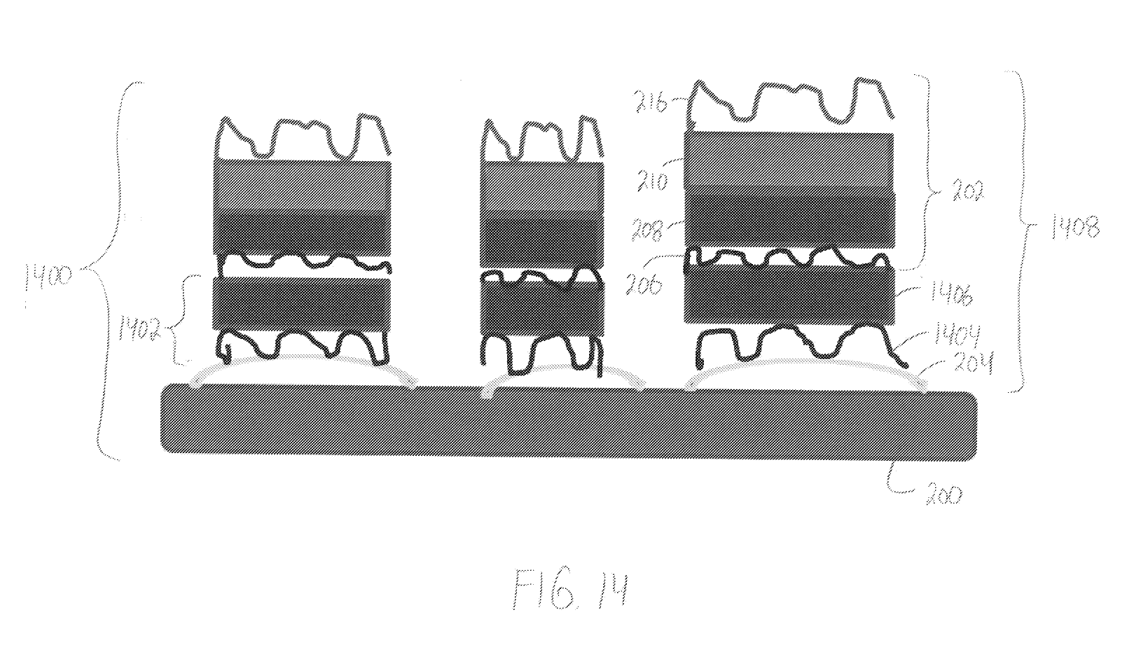

FIG. 11 is first magnified image of the conductive body 114 in the foil assembly 202 (shown in FIG. 2) that includes the composite polymer layer 210 (shown in FIG. 2). FIG. 12 is a second magnified image of the conductive body 114 shown in FIG. 11, and FIG. 13 is a third magnified image of the conductive body 114. The images shown in FIGS. 11 through 13 are at a two hundred magnification level.

The foil assembly 202 having the conductive body 114 in FIGS. 11 through 13 may be formed from aluminum that is deposited in a thickness that is sufficiently large to cause the optical density of the metallic layer 208 (shown in FIG. 2) that includes the conductive body 114 to be greater than 2.0. Additionally, this foil assembly includes the composite polymer layer 210 having a ratio of the amount of pigments 212 (shown in FIG. 2) to the amount of resin body 214 (shown in FIG. 2) that is at least 0.5 and that is less than one. Optionally, another ratio may be used. Additionally or alternatively, the resin body 214 may be formed from isoborneol-methyl methacrylate copolymer (or another material).

As shown in FIGS. 11 through 13, the conductive body 114 has no cracks or substantially no cracks relative to the conductive bodies 500, 700, 900 shown in FIGS. 5 through 10. Increasing the thickness of the metallic layer in the foil assembly 202 and/or providing the pigments 212 and the resin body 214 in the composite polymer layer 210 to have a ratio that is at least 0.5 and that is less than one unexpectedly eliminates or substantially eliminates the presence of cracks. For example, while some decrease in the size and/or number of cracks may occur by increasing the thickness of the conductive body 114 and/or changing the amount of pigments 212 in the resin body 214 of the composite polymer layer 210, the cracks are unexpectedly eliminated when the ratio of pigments 212 to resin body 214 is at least 0.5 and that is less than one.

This unexpected benefit of the conductive body 114 is further exemplified by the unexpectedly large successful read rates of the printed product apparatuses that include the foil assemblies 202 with the conductive body 114 shown in FIGS. 11 through 13. The read rates of these printed product apparatuses were measured to have successful read rates of at least 99.5%. As a result, five or fewer printed product apparatuses out of 1,000 printed product apparatuses having the conductive bodies 114 may not be able to be read by the touch-sensitive computing device, while at least 995 out of the 1,000 printed product apparatuses were able to be read. This stark increase in successful read rates represents another unexpected benefit from at least one embodiment of the inventive subject matter described herein.

In one or more of the printed product apparatuses that include the foil assemblies with the conductive bodies 500 and/or 700 (shown in FIGS. 5 through 8), a varnish or other coating may need to be applied in order to cause the exposed surface of the printed product apparatus to have a desired appearance, such as that of paper, card stock, or the like. But, due to the presence of the pigments 212 in the composite polymer layers of the foil assemblies that include the conductive bodies, no additional varnish or other coatings may be needed. The pigments 212 may sufficiently color the exposed surface of the printed product apparatus that the surface has the desired appearance, such as that of white paper, card stock, or the like.

In one example of the inventive subject matter described herein, a highly flexible polymeric layer (e.g., one, but not all embodiments of the tie coat layer 206 and/or the top coat layer 216) includes polymers like ones in the polyurethane or acrylic urethane class that are synthesized using one or a combination of polyester polyol, polyether polyol, polycarbonate polyol, acrylic polyol, or the like. This layer provides a smooth release from a PET film (e.g., one, but not all embodiments of the carrier body 300) and adheres to the composite polymer layer 210 described above. After drying of the polymer layer 210, the top coat layer 216 can provide a minimum surface tension dyne levels in the excess of 42 dynes and reaching over 50 dynes, thus enabling good flow of inks printed thereon and promoting adhesion to the polymer layer 210. The top coat layer 216 may have a percent elongation at break in the range of 100% to 500%, such as in the 150% to 350% range (or another value).

The highly flexible polymeric layer (e.g., one, but not all embodiments of the tie coat layer 206 and/or the top coat layer 216) can be applied by printing using gravure technique (either direct or reverse), the slot dye technique, or another technique.

This highly flexible polymeric layer (e.g., one, but not all embodiments of the tie coat layer 206 and/or the top coat layer 216) can be dried after application so that the surface tension dyne level reached is at least in the excess of 42 and preferably over 50 dynes, or at another value.

The pigmented polymeric layer (e.g., one, but not all embodiments of the polymer layer 210) can be applied in tandem with the highly flexible polymer (e.g., one, but not all embodiments of the top coat layer 216), or separately after the application of the flexible polymer is completed.

The pigmented polymeric layer (e.g., one, but not all embodiments of the polymer layer 210) after drying can have a dyne level which is at least 5 dynes lower than the flexible polymeric coating (e.g., one, but not all embodiments of the top coat layer 216). This can assist the flow and adhesion of the pigmented polymeric primer layer.

The pigmented polymeric layer (e.g., one, but not all embodiments of the polymer layer 210) can combine properties of brittleness due to a relatively high glass transition temperature (e.g., between 125 degrees Celsius and 165 degrees Celsius, or another value).

The pigmented polymeric layer (e.g., one, but not all embodiments of the polymer layer 210) can have relatively good adhesion with the top coat layer 216), and thereby provide for sharp and clean separation from a polyethylene terephthalate carrier (e.g., one, but not all embodiments of the carrier body 300) due to brittleness of the pigmented polymeric layer. This can allow for printing or other application of the patterns 112 with sharp definitions of the conductive bodies 114 that form the patterns 112.

The pigmented polymeric layer (e.g., one, but not all embodiments of the polymer layer 210) is brittle enough to allow the foil assembly to separate from the carrier body 300 while having the patterns 112 with sharp definitions of the conductive bodies 114 on flexible or rigid substrates (e.g., one, but not all embodiments of the substrate 200).

The pigmented polymeric layer (e.g., one, but not all embodiments of the polymer layer 210) can be sufficiently flexible due to a molecular weight of at least 100,000 Daltons (or another value), thus also contributing to the overall flexibility of the foil assembly.

In another embodiment, a polymeric pigmented layer (e.g., one, but not all embodiments of the polymer layer 210) is a polar layer with a relatively high acid value of at least 25 (or another value), thereby providing improved conditions (relative to a non-polar material and/or lower acid value) to disperse the pigment 212 in a selected or designated pigment-to-binder ratio in order to provide sufficient opacity to the pigmented layer to visibly hide the patterns 112 and/or conductive bodies 114 from an ordinary human being without aid of a magnifying device.

The pigment-to-binder ratio in the polymeric pigmented layer (e.g., one, but not all embodiments of the polymer layer 210) is at least 0.5 but less than 1. Alternatively, another range of ratios may be used.

The pigment 212 can be dispersed in the pigmented polymeric layer (e.g., one, but not all embodiments of the polymer layer 210) to reduce, minimize, or eliminate the addition of more varnishes or other layers to hide the patterns 112 and/or conductive bodies 114, thereby reducing the manufacturing cost and/or time of the printed product apparatuses.

The dispersion of the pigment 212 in the polymer layer 210 can strengthen the structural integrity of the foil assembly 202, which may not otherwise be possible if the color or opacity of the printed product apparatus is provided by varnishing a non-pigmented silver foil or laminate onto the foil assembly 202. Such a non-pigmented foil may tend to crack as the oxidative glue cures.

The metallic layer 208 of the foil assembly may be a vacuum metallized aluminum layer having a thickness of greater than 2.0 optical density (or another value) to reduce or minimize the number of cracks in the conductive bodies 114.

A highly flexible polymeric layer (e.g., one, but not all embodiments of the tie coat layer 206) may include one or more polymers like ones in the polyurethane or acrylic urethane class that are synthesized using one or a combination of polyester polyol, polyether polyol, polycarbonate polyol, acrylic polyol, or the like (or other materials), to provide improved adhesion to the metallic layer 208. This flexible polymeric layer may have surface tension dyne levels in excess of 42 dynes, greater than 50 dynes, or another value, after complete drying in order to provide improved adhesion to offset oxidative glue (e.g., one, but not all embodiments of the adhesive 204). This highly flexible polymeric layer can be selected so that the layer has a percent elongation at break in the range of 100% to 350%, in the 100% to 300% range, or another value or range.

The highly flexible polymeric layer (e.g., one, but not all embodiments of the tie coat layer 206) can be applied using a printing technique, such as gravure technique (e.g., direct or indirect), the slot dye technique, or another technique.

The highly flexible polymeric layer (e.g., one, but not all embodiments of the top coat layer 216) can be applied in a thickness range of 0.1 to 0.5 microns, 0.1 to 0.2 microns, or another thickness or range of thicknesses.

The pigmented polymeric layer (e.g., one, but not all embodiments of the polymer layer 210) can be applied in a thickness range of 1.5 microns to 5 microns, more specifically 1.9 microns to 2.5 microns, or another thickness or range of thicknesses.

The highly flexible polymeric layer (e.g., one, but not all embodiments of the tie coat layer 206) is applied in thickness of 0.05 to 0.1 microns, or in another thickness or range of thicknesses.

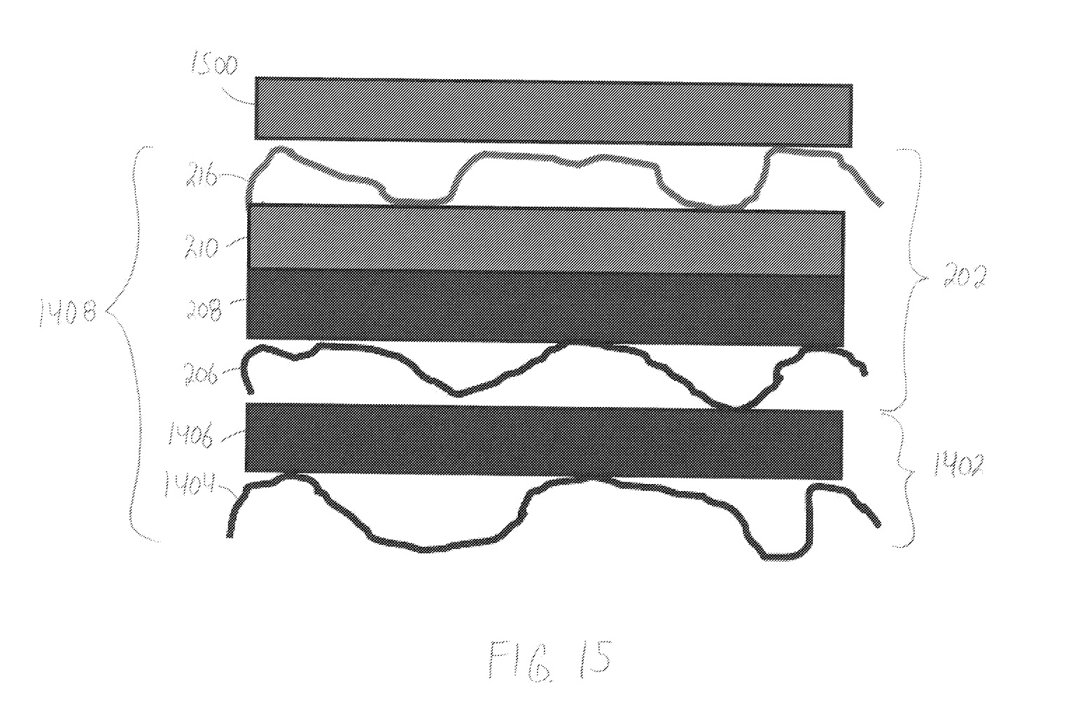

FIG. 14 is a cross-sectional view of another example of a printed product apparatus 1400. The apparatus 1400 may be used in place of or in addition to the printed product apparatus 102 shown in FIG. 1. The apparatus 1400 is shown in FIG. 14 as a cross-sectional view along the line A-A. For example, the embodiment of the apparatus 1400 shown in FIG. 14 may be shown as though the apparatus 1400 is in place of the apparatus 102 in FIG. 1 and is shown in FIG. 14 as a cross-sectional view along the line A-A.

The apparatus 1400 includes the substrate 200, which is coupled with a multi-layered foil assembly 1408 by the adhesive 204. In the illustrated example, the multi-layered foil assembly includes the foil assembly 202 of the apparatus 102 shown in FIG. 2, along with an additional foil assembly 1402. Optionally, the multi-layered foil assembly 1408 may have more than one foil assembly 1402 and/or more than one foil assembly 202.

The foil assembly 1402 may be referred to as a lower foil assembly and the foil assembly 202 referred to as an upper foil assembly because the foil assembly 1402 may be closer to the substrate 200 than the foil assembly 202. Additionally or alternatively, the foil assembly 1402 may be referred to as a coupling foil assembly because the foil assembly 1402 couples the foil assembly 202 to the substrate 200. Additionally or alternatively, the foil assembly 1402 can be referred to as an intermediate foil assembly because the foil assembly 1402 is between the foil assembly 202 and the substrate 200.

The adhesive 204 may couple the foil assembly 1402 to the substrate 200. The adhesive 204 can be applied in discrete locations, such as by forming spaced-apart islands of the adhesive 204. Optionally, a continuous sheet of adhesive 204 can extend between the substrate 200 and the foil assembly 1402. While only three islands of the adhesive 204 are shown, optionally, a fewer or larger number of islands of the adhesive 204 may be used.

In the illustrated embodiment, the foil assembly 1402 includes several layers stacked upon each other between the foil assembly 202 and the substrate 200. These layers can include a lower flexible tie coat layer 1404 that is coupled with the adhesive 204 and a lower metallic layer 1406 that is coupled with the tie coat layer 1404 and the foil assembly 202. The tie coat layer 1404 can be formed from the same materials and/or have the same dimensions as the tie coat layer 206 described above. The metallic layer 1406 can be formed from the same materials and/or have the same dimensions as the metallic layer 208 shown in FIG. 2. As described above in connection with FIG. 2, the scale of FIG. 14 may be different from that of FIG. 1 so that bodies 114 in the metallic layer 1406 are more visible in FIG. 1.

The foil assembly 1402 and the foil assembly 202 can be adhered to the substrate 200 by forming the foil assembly 1402 and the foil assembly 202 on a carrier body, delaminating the foil assemblies 1402, 202 from the carrier body, and then transferring the foil assemblies 1402, 202 onto the substrate 200, similar to as described above in connection with the foil assembly 202 shown in FIG. 2.

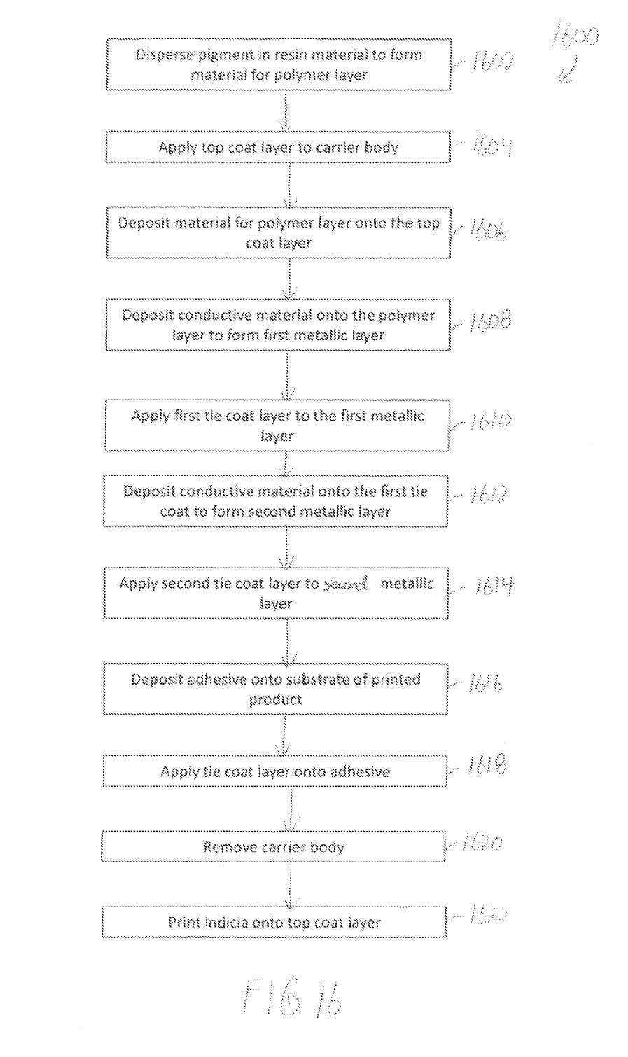

FIG. 15 is a cross-sectional view of the multi-layered foil assembly 1408 on a carrier body 1500 according to one example of the inventive subject matter described herein. The carrier body 1500 may be similar or identical to the carrier body 300 shown in FIG. 3. For example, the carrier body 1500 can be formed from a material that temporarily bonds with the top coat layer 216 of the foil assembly 202 that is part of the multi-layered foil assembly 1402.

The top coat layer 216 of the foil assembly 202 may be coupled with the carrier body 1500, and the pigmented polymer layer 210 deposited thereon, such as by printing the polymer layer 210 onto the top coat layer 216. The metallic layer 208 may then be deposited onto the polymer layer 210. Alternatively, another deposition technique may be used. For example, the metallic layer 208 can be deposited onto the polymer layer 210, as described above. Optionally, another material and/or deposition technique may be used to deposit the metallic layer 208. The tie coat layer 206 can then be applied to the metallic layer 208 to complete formation of the foil assembly 202. The metallic layer 1406 can be coupled with the tie coat layer 206 of the foil assembly 202 on one side and with the tie coat layer 1404 on the opposite side to form the assembly 1402.

The multi-layered foil assembly 1408 may then be coupled with the substrate 200 (as shown in FIG. 14) by depositing the adhesive 204 (as shown in FIG. 14) onto the substrate 200 and coupling the tie coat layer 1404 to the adhesive 204. As described above, the adhesive 204 can be printed onto the substrate 200 in the patterns 112 (shown in FIG. 1) such that, once the foil assembly 1402 is bonded to the substrate 200 by the adhesive 204, the carrier body 1500 can be separated from the substrate 200 and the portions of the foil assembly 1402 that are in contact with the adhesive 204 remain on the substrate 200. The tie coat layer 1404 may be more strongly bonded to the adhesive 204 than the top coat layer 216 is bonded to the carrier body 1500. As a result, the carrier body 1500 can be removed from the foil assembly 1408, with the foil assembly 1408 remaining coupled with the substrate 200 by the adhesive 204.

Adding the foil assembly 1402 to the foil assembly 202 (to form the multi-layered foil assembly 1408) can increase the useful life or shelf life of the printed product apparatus 1400 relative to a printed product apparatus having only one foil assembly. Long-term storage of a printed product apparatus 102, 1400 (e.g., storage over six months or more) can expose the apparatus 102, 1400 to extreme conditions such as high and/or low humidity, hot and/or cold temperatures, repeated handling by persons, etc. Adding the foil assembly 1402 to the foil assembly 202 can provide additional flexibility to the apparatus 1400 relative to the apparatus 102, which can thereby increase the useful life or service life of the apparatus 1400 over the apparatus 102.

Additionally, the addition of the foil assembly 1402 can increase the opacity of the polymer layers (e.g., the layers 210), which can make the patterns 112 even more difficult or impossible to view by an ordinary human being without aid of magnifying devices. Both the pigments 212 in the polymer layer 210 and the metallic layers 208, 1406 can at least partially reflect light and thereby make the patterns 112 less likely to be seen by a human being. For example, aluminium has about 20% to 35% transmission of light at thicknesses under 1.2 OD. Using aluminum in the metallic layers 208 and/or 1406 at thicknesses providing a total OD of the metallic layers 208, 1406 of at least 4 or more than 5 can allow very little or no light to be transmitted through the layers 208, 1406 and/or can reflect all or almost all of the light. This can cause enhanced light scattering, can make the foil assembly 1402 very opaque, and can prevent the patterns 112 from being visible.

The presence of two metallic layers 208, 1406 in the foil assembly 1408 provides increased mechanical robustness of the apparatus 1400 relative to the apparatus 102 because, if a crack is formed in the upper metallic layer 208 due to exposure from extreme conditions or otherwise, then it becomes less likely that the crack is present or formed exactly at the same location or spot on the lower metallic layer 1406 (relative to the apparatus 102). This can help the apparatus 1400 to maintain conductivity relative to the apparatus 102 because continuous circuitry may still be present even with cracks in one of the metallic layers 208, 1406. Similarly, a crack formed in the lower metallic layer 1406 may not cause a crack to be formed on the upper metallic layer 208 at the same location. Apparatuses 1408 (e.g., cards) produced with this structure can be active after six months or longer.

The presence of the tie coat layer 206 between the metallic layers 208, 1406 in the foil assembly 1408 can provide the flexibility that prevents cracks formed in one metallic layer 208 or 1406 from propagating into and forming a crack in the same location (e.g., directly underneath or above) in the other metallic layer 1406 or 208. For example, the stress or strain causing formation of a first crack in the upper metallic layer 208 can be at least partially absorbed by the tie coat layer 206 to thereby prevent the stress or strain from causing formation of a second crack in the lower metallic layer 1406 beneath the first crack.

FIG. 16 illustrates a flowchart of another method 1600 for manufacturing a printed product apparatus having a foil assembly that is readable by a touch-sensitive computing device. The method 1600 may be used to create the foil assembly 1402 and the printed product apparatus 1400 described above.

At 1602, a refractive pigment is dispersed within a resin material to form a composite material. For example, bodies of titanium oxide can be ground up and mixed in with isoborneol-methyl methacrylate copolymer to form the material that is to be used to form the polymer layer 210 (shown in FIG. 2).

At 1604, a top coat layer is coupled with a carrier body. For example, the top coat layer 216 (shown in FIG. 2) may be temporarily connected with the carrier body 1500 (shown in FIG. 15). In one aspect, the top coat layer may be applied by printing the top coat layer onto the carrier body, such as using the gravure printing technique, a slot dye technique, or another technique.

At 1606, the composite material formed at 1602 may be deposited onto the top coat layer. In one example, the composite material may be printed onto the top coat layer to form separate, spaced-apart bodies or islands of the polymer layer 210. In one aspect, the polymer layer and the top coat layer may be printed onto the carrier body at the same time. For example, the top coat layer and the polymer layer may be applied to the carrier body in tandem. Alternatively, the polymer layer may be separately formed on the top coat layer after the top coat layer is applied to the carrier body. The polymer layer may have a lower surface tension dyne level than the top coat layer after the polymer layer dries or cures. For example, the polymer layer 210 may have a surface tension dyne level that is at least five dynes lower than the top coat layer 216.

At 1608, one or more conductive materials are deposited into the polymer layer to form a first metallic layer. The conductive materials may be deposited using vacuum deposition or another technique. This metallic layer may be the layer 208.

At 1610, a first tie coat layer is applied to the first metallic layer. For example, the tie coat layer 206 (shown in FIG. 2) may be applied onto and coupled with the metallic layer 208 (shown in FIG. 2).

At 1612, one or more conductive materials are deposited into the first tie coat layer to form a second metallic layer. The conductive materials may be deposited using vacuum deposition or another technique. This metallic layer may be the layer 1406. At 1614, a second tie coat layer is applied to the second metallic layer. For example, the tie coat layer 1404 may be applied onto and coupled with the metallic layer 1406.

At 1616, adhesive is applied to a substrate of a printed product apparatus. For example, the adhesive 204 (shown in FIG. 2) may be printed onto the substrate 200 (shown in FIG. 2) at or near locations where the bodies 114 and patterns 112 formed by the polymer layer 210 and metallic layer 208 are to be located.

At 1618, the tie coat layer of the foil assembly 1402 is applied to (e.g., connected with) the adhesive. The adhesive may then cure to bind the foil assembly to the substrate of the printed product apparatus. As described above, the adhesive may change shape (e.g., shrink) during this curing process. The flexible top coat layer and tie coat layer, as well as the flexibility of the polymer layer, can more easily flex and move due to the changing shape of the adhesive so that the metallic layer is not bent or otherwise experience forces exerted on the metallic layer by the changing shape of the adhesive.

At 1620, the carrier body can be removed from the foil assembly 1402. During or after curing of the adhesive is complete, the carrier body can be separated from the top coat layer to leave portions of the foil assembly on the substrate. The portions of the foil assembly that remain on the substrate may be those portions that contact the adhesive on the substrate.

At 1622, indicia optionally may be printed onto the top coat layer of the foil assembly 1402, as described above. The printed product apparatus may then be placed onto a touch-sensitive input screen 104 (shown in FIG. 1) of a touch-sensitive computing device 100. The touch-sensitive computing device 100 may detect the conductive bodies 114 and/or patterns 112 of the bodies 114 based on changes in capacitance in one or more locations near the touch-sensitive input screen 104. Based on these changes in capacitance, the touch-sensitive computing device 100 may detect information represented by the bodies 114 and/or patterns 112, and use this information to take one or more responsive actions, such as display a website to a user, verify or authenticate a user (based on that user's possession of the printed product apparatus), present other information to the user (other than the information presented on the printed product apparatus), or the like.

In one example of the inventive subject matter described herein, a foil assembly of a printed product apparatus includes a metallic layer and a polymer layer. The metallic layer forms conductive bodies configured to be detected by a touch-sensitive computing device when the printed product apparatus is placed in contact with or near the touch-sensitive computing device in order for the touch-sensitive computing device to read information from the metallic layer. The polymer layer is coupled with the metallic layer and includes a pigment dispersed within a binder material. The pigment is at least one of reflective or opaque and the binder material is at least partially flexible. The polymer layer absorbs changes in shape of an adhesive that couples the metallic layer and the polymer layer to the printed product apparatus to prevent cracking of the metallic layer.

In one aspect, the foil assembly also includes a flexible top coat and a flexible tie coat layer. The flexible top coat is coupled with the polymer layer and forms an exposed surface of the printed product apparatus that is configured to be printed upon with one or more inks. The flexible tie coat layer is coupled with a substrate of the printed product apparatus by the adhesive. The polymer layer and the metallic layer are disposed between the flexible top coat and the flexible tie coat layer.

In one aspect, the flexible top coat has a surface tension dyne level of at least 42 dynes.

In one aspect, the polymer layer has a surface tension dyne level that is at least five dynes less than the surface tension dyne level of the flexible top coat.

In one aspect, at least one of the flexible top coat or the flexible tie coat layer has a percent elongation at break of 100% to 500%.

In one aspect, the percent elongation at break of the at least one of the flexible top coat or the flexible tie coat is in a range of 150% to 350%.

In one aspect, the polymer layer includes the pigment and the binder material in a pigment-to-binder ratio that is at least 0.5 and less than 1.

In one aspect, the polymer layer has a glass transition temperature of between 125 degrees Celsius and 165 degrees Celsius and a molecular weight of at least 100,000 Daltons.

In one aspect, the metallic layer has a thickness dimension that causes an optical density of the metallic layer to be at least two.

In another example of the inventive subject matter described herein, a method includes dispersing a pigment that is at least one of reflective or opaque in a binder material that is at least partially flexible to form a polymer layer, coupling the polymer layer to a metallic layer to form a foil assembly, and transferring the foil assembly to a substrate of a printed product apparatus with an adhesive that changes shape during curing of the adhesive. The adhesive can be provided on the substrate in one or more patterns such that, when the metallic layer and polymer layer are adhered to the substrate by the adhesive, one or more conductive bodies in the metallic layer are arranged in the one or more patterns and are configured to be detected by a touch-sensitive computing device when the printed product apparatus is placed in contact with or near the touch-sensitive computing device in order for the touch-sensitive computing device to read information from the metallic layer. The polymer layer absorbs changes in the shape of the adhesive to prevent cracking of the metallic layer.

In one aspect, the method also includes coupling a flexible top coat with the polymer layer. The flexible top coat forms an exposed surface of the printed product apparatus that is configured to be printed upon with one or more inks. The method also can include coupling a flexible tie coat layer with a substrate of the printed product apparatus by the adhesive such that the polymer layer and the metallic layer are disposed between the flexible top coat and the flexible tie coat layer.

In one aspect, the flexible top coat is coupled to the polymer layer by coating the flexible top coat onto a carrier body and applying the polymer layer to the flexible top coat that is coated onto the carrier body.

In one aspect, transferring the foil assembly includes coupling the flexible tie coat layer to the substrate with the adhesive and separating the carrier body from the flexible top coat.

In one aspect, dispersing the pigment in the binder material comprises mixing the pigment into the binder material in a pigment-to-binder ratio that is at least 0.5 and less than 1.

In one aspect, the polymer layer has a glass transition temperature of between 125 degrees Celsius and 165 degrees Celsius and a molecular weight of at least 100,000 Daltons.

In one aspect, the method also includes depositing the metallic layer onto the polymer layer at a thickness that causes an optical density of the metallic layer to be at least two.

In another example of the inventive subject matter described herein, a printed product apparatus includes a substrate formed from at least one of paper, card stock, or cardboard, and a foil assembly coupled with the substrate by an adhesive. The foil assembly includes a metallic layer having plural conductive bodies arranged in one or more patterns and a polymer layer comprising a pigment that is at least one of reflective or opaque dispersed in a binder material. The conductive bodies are arranged in the one or more patterns such that placement of the substrate or foil assembly on or near a touch screen of a touch-sensitive computing device causes the touch-sensitive computing device to detect the one or more patterns and take one or more responsive actions. The polymer layer is at least partially flexible in order to absorb changes in shape of the adhesive and prevent cracking in the metallic layer.

In one aspect, a pigment-to-binder ratio of the polymer layer is at least 0.5 and less than one.

In one aspect, the metallic layer is in a thickness that causes the metallic layer to have an optical density of at least two.

In one aspect, the printed product apparatus also includes a flexible top coat layer coupled with the polymer layer and configured to be printed upon by one or more inks, and a flexible tie coat layer coupled with the metallic layer and with the substrate.

In another example of the inventive subject matter described herein, a method includes dispersing a pigment that is at least one of reflective or opaque in a binder material that is at least partially flexible to form a polymer layer, and coupling the polymer layer and a tie coat layer to a such that the metallic layer is between the polymer layer and the tie coat layer. The metallic layer has conductive bodies arranged in one or more patterns. The method also includes adhering the tie coat layer to a substrate of a printed product apparatus by heating the tie coat layer so that the tie coat layer at least partially melts and adheres to the substrate. The one or more patterns of the conductive bodies in the metallic layer are configured to be detected by a touch-sensitive computing device when the printed product apparatus is placed in contact with or near the touch-sensitive computing device in order for the touch-sensitive computing device to read information from the metallic layer. The polymer layer absorbs changes in the shape of the tie coat layer to prevent cracking of the metallic layer.

In one aspect, the method also includes coupling a flexible top coat with the polymer layer. The flexible top coat forms an exposed surface of the printed product apparatus that is configured to be printed upon with one or more inks.

In one aspect, dispersing the pigment in the binder material comprises mixing the pigment into the binder material in a pigment-to-binder ratio that is at least 0.5 and less than 1.

In one aspect, the polymer layer has a glass transition temperature of between 125 degrees Celsius and 165 degrees Celsius and a molecular weight of at least 100,000 Daltons.

In one aspect, the method also includes depositing the metallic layer onto the polymer layer at a thickness that causes an optical density of the metallic layer to be at least two.

In another example of the inventive subject matter described herein, a printed product apparatus includes a substrate and a foil assembly. The substrate is formed from at least one of paper, card stock, cardboard, a polymeric film, a laminate film structure, polyvinyl chloride, polycarbonate, or a rigid polymeric body. The foil assembly is coupled with the substrate, and includes a metallic layer having plural conductive bodies arranged in one or more patterns, a polymer layer comprising a pigment that is at least one of reflective or opaque dispersed in a binder material, and a tie coat layer coupled to the substrate. The conductive bodies are arranged in the one or more patterns such that placement of the substrate or foil assembly on or near a touch screen of a touch-sensitive computing device causes the touch-sensitive computing device to detect the one or more patterns and take one or more responsive actions. The polymer layer is at least partially flexible in order to absorb changes in shape of the adhesive and prevent cracking in the metallic layer.

In one aspect, the tie coat layer is adhered to the substrate and is coupled with the metallic layer.

In one aspect, a pigment-to-binder ratio of the polymer layer is at least 0.5 and less than one.

In one aspect, the metallic layer is in a thickness that causes the metallic layer to have an optical density of at least two.

In one aspect, the printed product apparatus also includes a flexible top coat layer coupled with the polymer layer and configured to be printed upon by one or more inks.

In one aspect, the printed product apparatus also includes a second foil assembly that is coupled with and disposed between the first foil assembly and the substrate. The second foil assembly can be coupled with the substrate by the adhesive, and can include a metallic layer coupled with the polymer layer of the first foil assembly and a polymer layer coupled with the substrate by the adhesive.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the inventive subject matter without departing from its scope. While the dimensions and types of materials described herein are intended to define the parameters of the inventive subject matter, they are by no means limiting and are exemplary embodiments. Many other embodiments will be apparent to one of ordinary skill in the art upon reviewing the above description. The scope of the inventive subject matter should, therefore, be determined with reference to the appended clauses, along with the full scope of equivalents to which such clauses are entitled. In the appended clauses, the terms “including” and “in which” are used as the plain-English equivalents of the respective terms “comprising” and “wherein.” Moreover, in the following clauses, the terms “first,” “second,” and “third,” etc. are used merely as labels, and are not intended to impose numerical requirements on their objects. Further, the limitations of the following clauses are not written in means-plus-function format and are not intended to be interpreted based on 35 U.S.C. §112(f), unless and until such clause limitations expressly use the phrase “means for” followed by a statement of function void of further structure. For example, the recitation of a “mechanism for,” “module for,” “device for,” “unit for,” “component for,” “element for,” “member for,” “apparatus for,” “machine for,” or “system for” is not to be interpreted as invoking 35 U.S.C. §112(f) and any claim that recites one or more of these terms is not to be interpreted as a means-plus-function claim.

This written description uses examples to disclose several embodiments of the inventive subject matter, and also to enable one of ordinary skill in the art to practice the embodiments of inventive subject matter, including making and using any devices or systems and performing any incorporated methods. The patentable scope of the inventive subject matter is defined by the clauses, and may include other examples that occur to one of ordinary skill in the art. Such other examples are intended to be within the scope of the clauses if they have structural elements that do not differ from the literal language of the clauses, or if they include equivalent structural elements with insubstantial differences from the literal languages of the clauses.

As used herein, an element or step recited in the singular and proceeded with the word “a” or “an” should be understood as not excluding plural of said elements or steps, unless such exclusion is explicitly stated. Furthermore, references to “one embodiment” or “an embodiment” of the presently described inventive subject matter are not intended to be interpreted as excluding the existence of additional embodiments that also incorporate the recited features. Moreover, unless explicitly stated to the contrary, embodiments “comprising,” “comprises,” “including,” “includes,” “having,” or “has” an element or a plurality of elements having a particular property may include additional such elements not having that property.

What is claimed is:

1. A foil assembly of a printed product apparatus, the foil assembly comprising:
a metallic layer configured to be detected by a touch-sensitive computing device when the printed product apparatus is placed in contact with or near the touch-sensitive computing device in order for the touch-sensitive computing device to read information from the metallic layer; and
a polymer layer coupled with the metallic layer, the polymer layer including a pigment dispersed within a binder material, the pigment being at least one of reflective or opaque and the binder material being at least partially flexible, wherein the polymer layer absorbs changes in shape of an adhesive that couples the metallic layer and the polymer layer to the printed product apparatus to prevent cracking of the metallic layer.

2. The foil assembly of claim 1, further comprising:
a flexible top coat coupled with the polymer layer and forming an exposed surface of the printed product apparatus that is configured to be printed upon with one or more inks; and
a flexible tie coat layer coupled with a substrate of the printed product apparatus by the adhesive, wherein the polymer layer and the metallic layer are disposed between the flexible top coat and the flexible tie coat layer.

3. The foil assembly of claim 2, wherein the flexible top coat has a surface tension dyne level of at least 42 dynes.

4. The foil assembly of claim 3, wherein the polymer layer has a surface tension dyne level that is at least five dynes less than the surface tension dyne level of the flexible top coat.

5. The foil assembly of claim 2, wherein at least one of the flexible top coat or the flexible tie coat layer has a percent elongation at break of 100% to 500%.

6. The foil assembly of claim 5, wherein the percent elongation at break of the at least one of the flexible top coat or the flexible tie coat is in a range of 150% to 350%.

7. The foil assembly of claim 1, wherein the polymer layer includes the pigment and the binder material in a pigment-to-binder ratio that is at least 0.5 and less than 1.

8. The foil assembly of claim 1, wherein the polymer layer has a glass transition temperature of between 125 degrees Celsius and 165 degrees Celsius and a molecular weight of at least 100,000 Daltons.

9. The foil assembly of claim 1, wherein the metallic layer has a thickness dimension that causes an optical density of the metallic layer to be at least two.

10. A method comprising:
dispersing a pigment that is at least one of reflective or opaque in a binder material that is at least partially flexible to form a polymer layer;
coupling the polymer layer to a metallic layer to form a foil assembly; and
transferring the foil assembly to a substrate of a printed product apparatus with an adhesive that changes shape during curing of the adhesive, the adhesive arranged in one or more patterns on the substrate,
wherein the metallic layer is configured to be detected by a touch-sensitive computing device when the printed product apparatus is placed in contact with or near the touch-sensitive computing device in order for the touch-sensitive computing device to read information from the metallic layer, and
wherein the polymer layer absorbs changes in the shape of the adhesive to prevent cracking of the metallic layer.

11. The method of claim 10, further comprising:
coupling a flexible top coat with the polymer layer, the flexible top coat forming an exposed surface of the printed product apparatus that is configured to be printed upon with one or more inks; and
coupling a flexible tie coat layer with a substrate of the printed product apparatus by the adhesive such that the polymer layer and the metallic layer are disposed between the flexible top coat and the flexible tie coat layer.

12. The method of claim 11, wherein the flexible top coat is coupled to the polymer layer by coating the flexible top coat onto a carrier body and applying the polymer layer to the flexible top coat that is coated onto the carrier body.

13. The method of claim 12, wherein transferring the foil assembly includes coupling the flexible tie coat layer to the substrate with the adhesive and separating the carrier body from the flexible top coat.

14. The method of claim 10, wherein dispersing the pigment in the binder material comprises mixing the pigment into the binder material in a pigment-to-binder ratio that is at least 0.5 and less than 1.

15. The method of claim 10, wherein the polymer layer has a glass transition temperature of between 125 degrees Celsius and 165 degrees Celsius and a molecular weight of at least 100,000 Daltons.

16. The method of claim 10, further comprising depositing the metallic layer onto the polymer layer at a thickness that causes an optical density of the metallic layer to be at least two.

17. A printed product apparatus comprising:
a substrate formed from at least one of paper, card stock, cardboard, a polymeric film, a laminate film structure, polyvinyl chloride, polycarbonate, or a rigid polymeric body; and
a first foil assembly interconnected with the substrate by an adhesive, the first foil assembly comprising a metallic layer having plural conductive bodies arranged in one or more patterns and a polymer layer comprising a pigment that is at least one of reflective or opaque dispersed in a binder material, the conductive bodies arranged in the one or more patterns such that placement of the substrate or foil assembly on or near a touch screen of a touch-sensitive computing device causes the touch-sensitive computing device to detect the one or more patterns and take one or more responsive actions,
wherein the polymer layer is at least partially flexible in order to absorb changes in shape of the adhesive and prevent cracking in the metallic layer.

18. The printed product apparatus of claim 17, wherein the metallic layer is in a thickness that causes the metallic layer to have an optical density of at least two.

19. The printed product apparatus of claim 17, further comprising:
a flexible top coat layer coupled with the polymer layer and configured to be printed upon by one or more inks; and
a flexible tie coat layer coupled with the metallic layer and with the substrate.

20. The printed product apparatus of claim 17, further comprising a second foil assembly coupled with and disposed between the first foil assembly and the substrate, the second foil assembly coupled with the substrate by the adhesive, the second foil assembly including a metallic layer coupled with the polymer layer of the first foil assembly, the second foil assembly also including a polymer layer coupled with the substrate by the adhesive.
